(19) United States
(12) Patent Application Publication
(10) Pub. No.: US 2025/0123552 A1
(43) Pub. Date: Apr. 17, 2025

(54) LITHOGRAPHY MASK HAVING HIGH EXTINCTION COEFFICIENT ABSORBER AND RELATED SYSTEMS AND METHODS

(71) Applicant: Taiwan Semiconductor Manufacturing Co., Ltd., Hsinchu (TW)

(72) Inventors: Pei-Cheng HSU, Hsinchu (TW); Hsuan-I WANG, Hsinchu (TW); Ping-Hsun LIN, Hsinchu (TW); Ching-Fang YU, Hsinchu (TW); Chia-Jen CHEN, Hsinchu (TW); Hsin-Chang LEE, Hsinchu (TW)

(21) Appl. No.: 18/628,337

(22) Filed: Apr. 5, 2024

Related U.S. Application Data
(60) Provisional application No. 63/610,538, filed on Dec. 15, 2023.
(60) Provisional application No. 63/591,071, filed on Oct. 17, 2023.

(51) Int. Cl. G03F 1/58; G03F 1/24; G03F 1/76; G03F 1/80; G03F 7/00

(52) U.S. Cl. CPC G03F 1/58; G03F 1/24; G03F 1/76; G03F 1/80; G03F 7/70033

(57) ABSTRACT

An extreme ultraviolet (EUV) mask and method of forming an EUV mask are provided. The method includes forming a mask layer on a semiconductor wafer, generating extreme ultraviolet (EUV) light by a lithography exposure system, forming patterned EUV light by patterning the EUV light by a mask including an absorber having extinction coefficient at an EUV wavelength that exceeds extinction coefficients of TaBN and TaN at the EUV wavelength, and exposing the mask layer by the patterned EUV light.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of portions of a lithography scanner according to embodiments of the present disclosure.

FIGS. 2-9B are views of various embodiments of a system including a lithography apparatus and a fuel cell according to various aspects of the present disclosure.

FIGS. 10 and 11 are flowcharts of methods of forming a mask according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a number or a range of numbers is described with “about,” “approximately,” “roughly,” “substantially,” and the like, the term is intended to encompass numbers that are within a reasonable range including the number described, such as within +/−10% of the number described or other values as understood by person skilled in the art. As a non-limiting example, the term “about 5 nm” encompasses the dimension range from 4.5 nm to 5.5 nm.

The present disclosure is generally related to lithography equipment for fabricating semiconductor devices, and more particularly to a mask that includes a high-K absorber that improves exposure quality associated with use of an extreme ultraviolet (EUV) lithography apparatus. It should be understood that “high-K” in the context of the embodiments generally refers to a high extinction coefficient.

EUV mask blanks that have a thick absorber layer can suffer high M3D (Mask 3-Dimensional) effects, such light shadowing. The absorber material of EUV mask blanks affects high volume manufacturing of extreme ultraviolet (EUV) lithography. EUV production performance difficulties that can be introduced by the absorber material of the EUV mask are the M3D effect and increased exposure energy consumption due to thicker absorber material in some methods.

In embodiments of the disclosure, high-K materials are used as an EUV mask blank, such as a Ru-based material absorber. For example, the mask blank material in accordance with various embodiments may include a single layer or a dual layer of a Ru-based alloy, which can be PtRu, IrRu, OsRu, HfRu, RhRu, PtRuN, IrRuN, OsRuN, HfRuN, RhRuN, PtRuO, IrRuO, OsRuO, HfRuO, RhRuO, PtRuON, IrRuON, OsRuON, HfRuON, RhRuON or the like. A different type of hard mask layer and buffer layer can be included over the absorber to achieve improved patterning through dry etching. The hard mask layer can include 2, 3 or 4 layers combined with a buffer layer. Materials of the hard mask layer(s) and buffer layer can be Ta-based materials, Si-based materials or the like. As non-limiting examples, the hard mask layer(s) and/or the buffer layer may include TaBO, TaBN, TaN, Ta₂O₅, TaO₂, TaO, Ta₂O, MoSi, MoSiN, MoSiO, SiN, SiON, SiO₂, SiCON, SiC, SiCN, CrN, Cr₂N, or GaN.

The high-K materials of the EUV mask blank described herein can reduce M3D (Mask 3-Dimensional) effects. In the embodiments, high-K materials are used as the absorber layer for the EUV mask blank to reduce thickness of the absorber film, which in turn reduces M3D (Mask 3-Dimensional) effects, exposure energy, and improves image quality. For example, the high-K materials of EUV mask blank can reduce exposure energy and increase aerial image contrast through normalized image log slope (NILS) and low mask error enhancement factors (MEEF). Image log slope (ILS) can refer to a method of evaluating quality of spatial images. The larger the logarithmic slope value of imaging is, the higher the contrast of spatial imaging and the better the quality of imaging may be.

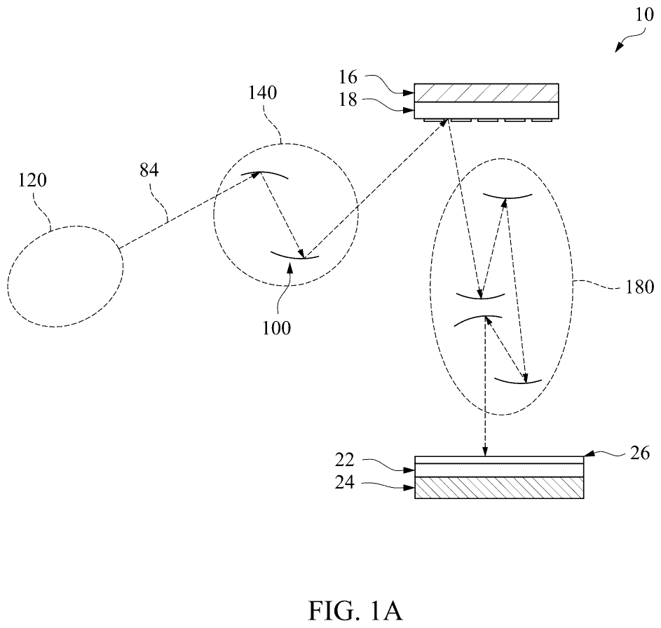

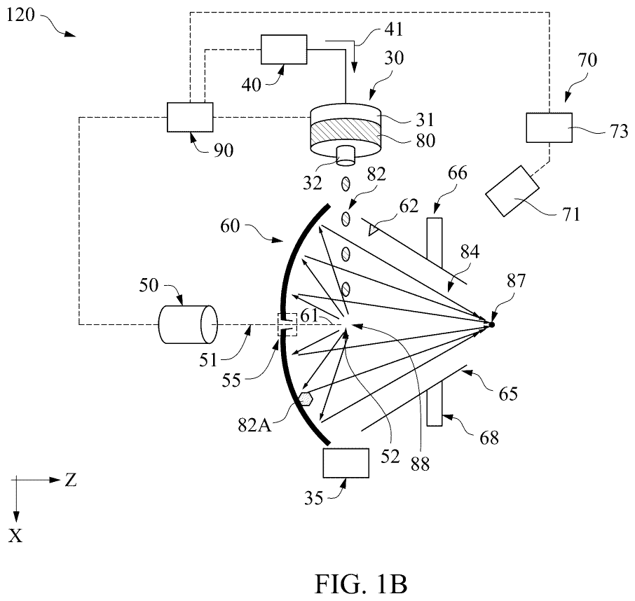

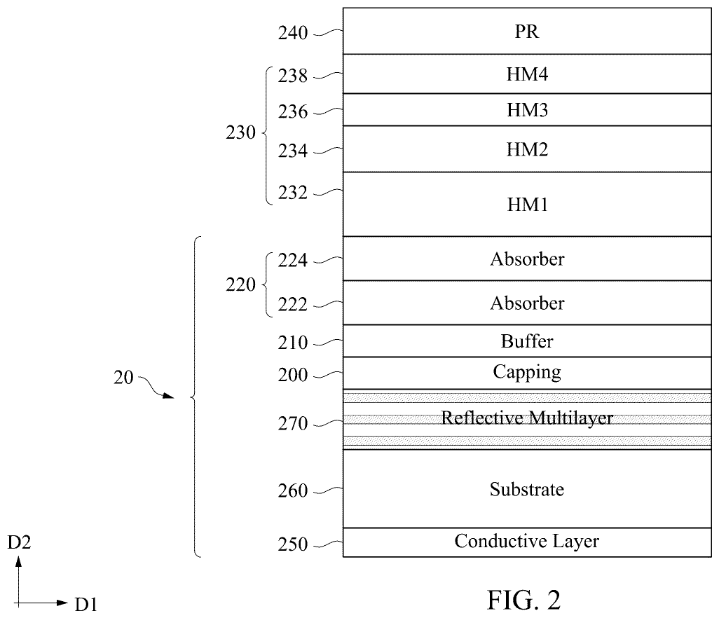

FIG. 1A is a schematic and diagrammatic view of a lithography exposure system or apparatus 10, in accordance with some embodiments. The lithography exposure system 10 is described in detail to provide context for understanding a mask 18 whose formation is described with reference to FIGS. 2-9B.

In some embodiments, the lithography exposure system 10 is an extreme ultraviolet (EUV) lithography system operable to expose a resist layer by EUV radiation and may also be referred to as the EUV system 10. The EUV system 10 may also be referred to as an EUV scanner or lithography scanner. The lithography exposure system 10 includes a light source 120, an illuminator 140, a mask stage 16, a projection optics module (or projection optics box (POB)) 180 and a substrate stage 24, in accordance with some embodiments. The elements of the lithography exposure system 10 can be added to or omitted, and the disclosure should not be limited by the embodiment.

The light source 120 is configured to generate light radiation having a wavelength ranging between about 1 nm and about 300 nm in certain embodiments. In one particular example, the light source 120 generates an EUV radiation with a wavelength centered at about or substantially 13.5 nm. Accordingly, the light source 120 is also referred to as an EUV radiation source. However, it should be appreciated that the light source 120 should not be limited to emitting EUV radiation. The light source 120 can be utilized to perform any high-intensity photon emission from excited target fuel.

In various embodiments, the illuminator 140 includes various reflective optic components, such as reflective optics 100 that include a single mirror or a mirror system having multiple mirrors in order to direct light from the light source 120 onto the mask stage 16, particularly to a mask 18 secured on the mask stage 16. In embodiments in which the light source 120 generates light in the EUV wavelength range, reflective optics are employed. In some embodiments, the illuminator 140 includes at least two reflectors, at least three reflectors, or more.

The mask stage 16 is operable to secure the mask 18. In the present disclosure, the terms mask, photomask, and reticle are used interchangeably. In the present embodiment, the mask 18 is a reflective mask. One example structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate. In some embodiments, the mask stage 16 includes an electrostatic chuck (e-chuck) that can secure the mask 18. One reason an e-chuck is beneficial is that gas molecules absorb EUV radiation and the e-chuck is operable in the lithography exposure system for the EUV lithography patterning that is maintained in a vacuum environment to avoid EUV intensity loss. The mask stage 16 is operable to translate in two horizontal directions, such as an X-axis direction and a Y-axis direction, so as to expose multiple different regions of the semiconductor wafer 22 to light having a pattern generated by the mask 18. The semiconductor wafer 22 may have a mask layer 26 thereon, which may be a photoresist layer that is sensitive to the light carrying the pattern of the mask 18.

The projection optics module (or projection optics box (POB)) 180 is operable to image the pattern of the mask 18 on to a semiconductor wafer 22 secured on the substrate or wafer stage 24 of the lithography exposure system 10. In some embodiments, the POB 180 has reflective optics. The light directed from the mask 18, carrying the image of the pattern on the mask, is collected by the POB 180. The illuminator 140 and the POB 180 may be referred to collectively as an optical module of the lithography exposure system 10. In some embodiments, the POB 180 includes at least six reflective optics although four are depicted in FIG. 1A.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), capacitors, inductors, diodes, and/or other applicable elements. Various processes are performed to form the device elements, such as deposition, etching, implantation, photolithography, annealing, and/or other suitable processes. In some embodiments, the semiconductor wafer 22 is coated with a resist layer sensitive to the EUV radiation. Various components including those described above are integrated together and are operable to perform lithography processes.

In FIG. 1B, the light source 120 is shown in a diagrammatical view, in accordance with some embodiments. In some embodiments, the light source 120 employs a dual-pulse laser produced plasma (LPP) mechanism to generate plasma 88 and further generate EUV radiation from the plasma. The light source 120 includes a droplet generator 30, a droplet receptacle 35, a laser generator 50, a laser produced plasma (LPP) collector 60, a monitoring device 70 and a controller 90. Some or all of the above-mentioned elements of the light source 120 may be held under vacuum. It should be appreciated that the elements of the light source 120 can be added to or omitted, and should not be limited by the embodiment.

The droplet generator 30 is operable to generate a plurality of droplets 82, which may be elongated, of a target fuel 80 to a zone of excitation at which at least one laser pulse 51 from the laser generator 50 hits the droplets 82, as shown in FIG. 1B. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120 at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is operable to generate at least one laser pulse to allow the conversion of the droplets 82 into plasma 88. In some embodiments, the laser generator 50 is operable to produce a laser pulse 51 to the lighting point 52 to convert the droplets 82 to plasma 88 which generates EUV radiation 84. The laser pulse 51 is directed through window (or lens) 55 and irradiates droplets 82 at the lighting point 52. The window 55 is formed in the collector 60 and adopts a suitable material substantially transparent to the laser pulse 51. The droplet receptacle 35 catches and collects unused droplets 82 and/or scattered material of the droplets 82 resulting from the laser pulse 51 striking the droplets 82. Some of the scattered material may settle on various components of the lithography exposure system 10, such as a collector 60 of the light source 120, which is nearest the tin droplets 82 as they are struck by the laser pulse 51.

The plasma emits EUV radiation 84, which is collected by the collector 60. The collector 60 further reflects and focuses the EUV radiation 84 for the lithography processes performed through an exposure tool. In some embodiments, the collector 60 has an optical axis 61 which is parallel to the z-axis and perpendicular to the x-axis. The collector 60 may include a single section, as shown, or at least two sections that are offset from each other in the z-axis direction.

The lithography exposure system 10 may include other modules or be integrated with (or be coupled with) other modules, such as a cleaning module or apparatus or system 62 operable to provide hydrogen gas to the light source 120 and a tin supply system operable to provide liquid tin to the light source 120. The hydrogen gas is beneficial to reduce contamination in the light source 120. The cleaning system 62 may clean a collector 60 of the light source 120, but is not limited thereto. For example, tin debris 82A may settle on a variety of components of the lithography exposure system 10, and the cleaning system 62 may expel the hydrogen gas toward the various components to remove the tin debris 82A.

The collector 60 may further include a vessel wall 65 having the cleaning system 62 and first and second pumps 66, 68 attached thereto. The cleaning system 62 may include one or more nozzles that may be directed toward areas of the lithography exposure system 10, such as the collector 60, to expel hydrogen gas at high pressure to remove the debris 82A from the surface of the collector 60. The cleaning by the cleaning system 62 is beneficial to maintain a mirror surface of the collector 60, which increases light output power by the light source 120 and improves wafer throughput.

In an embodiment, the laser generator 50 is a carbon dioxide (CO2) laser source. In some embodiments, the laser generator 50 is operable to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have selected driving power to meet wafer production targets, such as a throughput of 125 wafers per hour (WPH). For example, the laser pulse 51 is equipped with about 23 kW driving power. In various embodiments, the driving power of the laser pulse 51 is at least 20 kW, such as 27 kW.

The monitoring device 70 is operable to monitor one or more conditions in the light source 120 so as to produce data for controlling selectable parameters of the light source 120. In some embodiments, the monitoring device 70 includes a metrology tool 71 and an analyzer 73. In cases where the metrology tool 71 is operable to monitor condition of the droplets 82 supplied by the droplet generator 30, the metrology tool 71 may include an image sensor, such as a charge coupled device (CCD), complementary metal oxide semiconductor sensor (CMOS) sensor or the like. The metrology tool 71 produces a monitoring image including image or video of the droplets 82 and transmits the monitoring image to the analyzer 73. In cases where the metrology tool 71 is configured to detect energy or intensity of the EUV light 84 produced by the droplet 82 in the light source 120, the meteorology tool 71 may include a number of energy sensors. The energy sensors may be any suitable sensors that are operable to observe and measure energy of electromagnetic radiation in the ultraviolet region.

The analyzer 73 is operable to analyze signals produced by the metrology tool 71 and output a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are operable to monitor different conditions of the light source 120. One is operable to monitor condition of the droplets 82 supplied by the droplet generator 30, and the other is operable to detect energy or intensity of the EUV light 84 produced by the droplet 82 in the light source 120. In some embodiments, the metrology tool 71 is a final focus module (FFM) and positioned in the laser source 50 to detect light reflected from the droplet 82.

The controller 90 is operable to control one or more elements of the light source 120, for example, by selecting one or more parameters or variables of the element(s). In some embodiments, the controller 90 is operable to drive the droplet generator 30 to generate the droplets 82. In addition, the controller 90 is operable to drive the laser generator 50 to fire the laser pulse 51. The generation of the laser pulse 51 may be controlled to be associated with the generation of droplets 82 by the controller 90 so as to make the laser pulse 51 hit each target 80 in sequence. The controller 90 may be operable to control delivery of hydrogen gas and exhaust of spent hydrogen gas by the pumps 66, 68.

In some embodiments, the droplet generator 30 includes a reservoir 31 and a nozzle assembly 32. The reservoir 31 is configured for holding the target material 80. In some embodiments, one gas line 41 is connected to the reservoir 31 for introducing pumping gas, such as argon, from a gas source 40 into the reservoir 31. By controlling the gas flow in the gas line 41, the pressure in the reservoir 31 can be manipulated. For example, when gas is continuously supplied into the reservoir 31 via the gas line 41, the pressure in the reservoir 31 increases. As a result, the target material 80 in the reservoir 31 can be forced out of the reservoir 31 in the form of droplets 82. The reservoir 31 receives the target material 80, e.g., liquid tin, from a target supply system that may include one or more low-pressure reservoirs and one or more high-pressure reservoirs.

FIGS. 2-9B are diagrammatic views of a mask 20 at intermediate stages of formation in accordance with various embodiments. The mask 20 may include a high-K absorber layer or multilayer 220 that has reduced thickness and is beneficial to improve imaging quality.

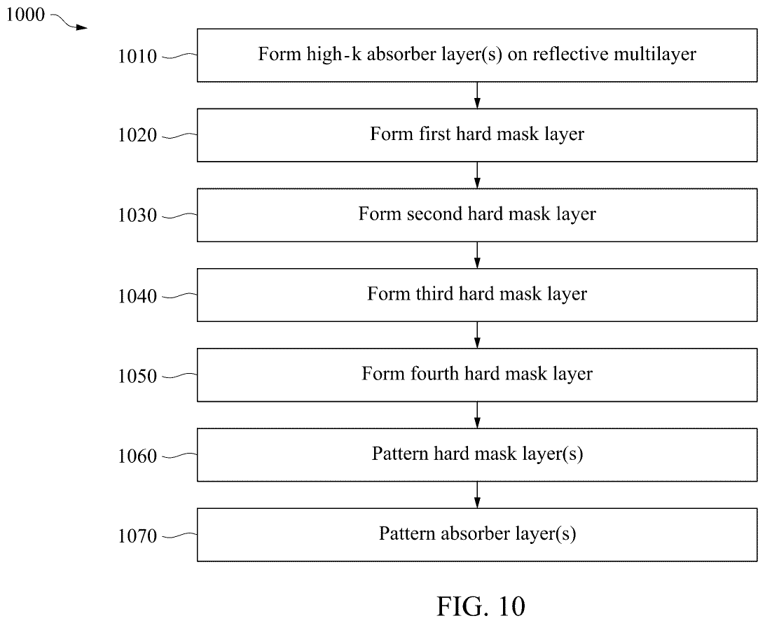

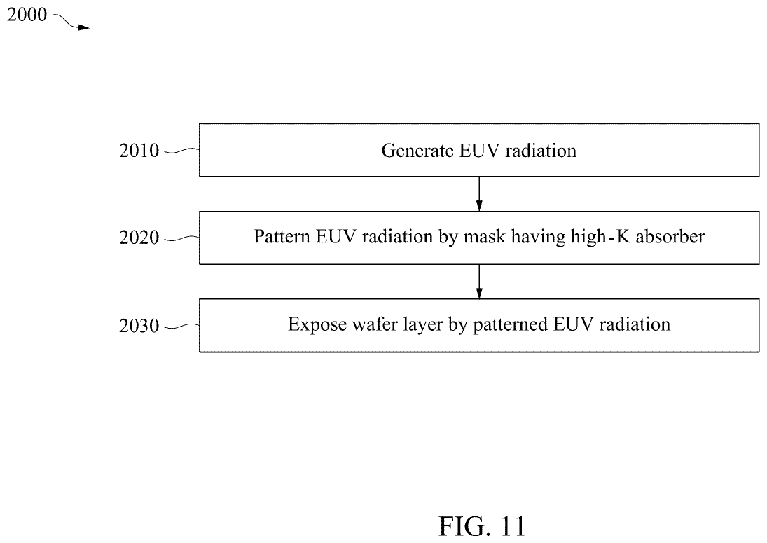

FIGS. 10 and 11 depict flowcharts of processes 1000, 2000 in accordance with various embodiments. In some embodiments, the process 1000 for forming a mask includes a number of operations (1010, 1020, 1030, 1040, 1050, 1060 and 1070). In some embodiments, the process 2000 for patterning a wafer layer via the mask having a high-K absorber includes operations (2010, 2020 and 2030). The processes 1000, 2000 will be further described according to one or more embodiments. It should be noted that the operations of the processes 1000, 2000 may be rearranged or otherwise modified within the scope of the various aspects. It should further be noted that additional processes may be provided before, during, and after the processes 1000, 2000, and that some other processes may be only briefly described herein. In some embodiments, the process 2000 is performed by the system 10 described in FIGS. 1A and 1B. The embodiments of the process 2000 are described with reference to the structural elements described in FIGS. 1A and 1B, but the process 2000 may be performed by a system having one or more structural elements that are different from those of the system 10.

FIG. 2 depicts an unpatterned mask 20 (or simply “mask 20”) having a hard mask structure 230 and a photoresist layer 240 thereon in accordance with various embodiments.

The mask 20 includes an absorber structure 220 on a reflective multilayer 270. The absorber structure 220 is operable to absorb incoming EUV light and the reflective multilayer 270 is operable to reflect the incoming EUV light. By patterning the absorber structure 220 to selectively expose regions of the reflective multilayer 270 according to a selected pattern, the pattern may be transferred by the mask 20 when exposed to light, such as EUV light 84 described with reference to FIGS. 1A and 1B. In some embodiments, microstructure of one or more layers 200, 210, 222, 224 of the mask 20 is in a polycrystalline range (e.g., grain size less than about 5 nm) or an amorphous range.

The reflective multilayer 270 may include alternating layers of materials such as molybdenum and silicon. In some embodiments, the reflective multilayer 270 includes one or more layers of materials having extinction coefficient K<0.02, such as Ru, Tc, Mo, Nb, Ti, Zr, Y, Sc, and the like. For example, the reflective multilayer 270 may include a stack of layers of molybdenum, silicon, ruthenium and strontium. The silicon and strontium layers may be referred to as spacer layers and the molybdenum and ruthenium layers may be referred to as reflector layers. The reflective multilayer 270 may include tens or hundreds of spacer/reflector layer pairs (or “bilayers”) stacked one on top of the other. Thicknesses of the individual layers may be uniform throughout the stack or may be varied throughout the stack (e.g., aperiodic). Individual thicknesses of each of the layers may be in a range of about 5 Angstroms to about 50 Angstroms. Arrangement of the bilayers may be uniform or non-uniform throughout the stack.

The absorber structure 220 is on the reflective multilayer 270 and may be or include a single layer or a multilayer. For example, as depicted in FIG. 2, the absorber structure 220 may be a multilayer that includes a first absorber layer 222 and a second absorber layer 224 on the first absorber layer 222. The first absorber layer 222 may have thickness in a range of about 5 nm to about 30 nm and may have grain size in a polycrystalline or amorphous range, such as less than about 5 nm. The second absorber layer 224 may have thickness in a range of about 10 nm to about 40 nm or in a range of about 20 nm to about 50 nm and may have grain size similar to that described for the first absorber layer 222. Overall thickness of the absorber structure 220 may be in a range of about 15 nm to about 80 nm. Generally, overall thickness of the absorber structure 220 is less than about 80 nm, less than about 60 nm or less than about 50 nm. Below about 50 nm, benefits of reduced M3D effect, reduced exposure energy and improved NILS are achieved. The thicknesses described may be measured along a second or vertical direction D2 depicted in FIG. 2. The absorber structure 220 may extend along a first or horizontal direction D1 that is transverse (e.g., perpendicular to) the second direction D2.

The first absorber layer 222 may be or include a ruthenium-based high-K material, which may be one or more of PtRu, IrRu, OsRu, HfRu, RhRu, PtRuN, IrRuN, OsRuN, HfRuN, RhRuN, RuTa, RuTaO, a bilayer of RuTa/RuTaO or the like. In some embodiments, the material may include ruthenium at an atomic concentration (“at %”) in a range of about 40% to about 70% and may include nitrogen in a range of about 2 at % to about 20 at %.

The second absorber layer 224 may be or include a ruthenium-based high-K material, which may be one or more of PtRuO, IrRuO, OsRuO, HfRuO, RhRuO, PtRuON, IrRuON, OsRuON, HfRuON, RhRuON, RuTa, RuTaO, a bilayer of RuTa/RuTaO or the like. In some embodiments, the material of the second absorber layer 224 includes ruthenium in a range of about 40 at % to about 70 at %, oxygen in a range of about 2 at % to about 20 at % and nitrogen in a range of about 2 at % to about 20 at %.

In some embodiments, the first or second absorber layer 222, 224 is omitted. Namely, the absorber structure 220 may include the first absorber layer 222, the second absorber layer 224 or both. In some embodiments, additional absorber layers similar to the first and/or second absorber layers 222, 224 are included in the absorber structure 220. Namely, the absorber structure 220 may include three or more absorber layers that include, for example, the first and/or second absorber layers 222, 224 just described as well as additional absorber layers similar to the first and/or second absorber layers 222, 224.

The first and second absorber layers 222, 224 are described above as including Ru-based high extinction coefficient materials. The extinction coefficient of the first and second absorber layers 222, 224 may be associated with an EUV wavelength, such as 13.5 nm. The Ru-based materials may be selected due to having extinction coefficients at the EUV wavelength that exceed those of TaBN and TaN at the EUV wavelength. In some embodiments, other materials that do not include ruthenium are included when the other materials have extinction coefficient(s) that exceed those of TaBN and TaN at the EUV wavelength.

In some embodiments, a capping layer 200 is present on an upper surface of the reflective multilayer 270. The capping layer 200 is present covering the reflective multilayer 270 to protect the reflective multilayer 270 from oxidation and other environmental damage. The capping layer 200 may be a ruthenium-based thin layer of one or more materials, such as Ru, RuO, RuNb, RuNbO, RuZr, RuZrN, RuRh, RuON, RuNbN, RuRhN, RuVO, RuV, RuVN or the like. Ruthenium may be selected for its beneficial stability and compatibility with EUV wavelengths. The capping layer 200 may have thickness in a range of about 2 nm to about 5 nm.

In some embodiments, a buffer or barrier layer 210 is present between the capping layer 200 and the absorber structure 220. The buffer layer 210 may be included between the reflective multilayer 270 and the absorber structure 220 to prevent damage to the capping layer 200 during etching of the absorber structure 220. The buffer layer 210 may be or include CrN, Cr2N or both. Thickness of the buffer layer 210 may be in a range of about 2 nm to about 20 nm. In some embodiments, the buffer layer 210 is omitted. The capping layer 200 may also serve a role as an etch stopping layer during removal of the buffer layer 210.

The multilayer reflector 270 is formed on or attached to a substrate 260, which may be or include a low thermal expansion material (LTEM), such as TiO₂ doped SiO₂, or other suitable materials. The LTEM substrate 260 is beneficial for maintaining structural integrity and optical performance of the multilayer reflector 270 under intense thermal load experienced during EUV lithography.

A conductive layer or multilayer 250 may be present on an underside of the substrate 260. The conductive layer 250 present on the underside of the substrate 260 may be used to attach the mask 20 to a mask stage via an electrostatic chuck. The conductive layer 250 may also improve thermal conductivity of the mask 20, such as by improving dissipation of heat generated by the e-chuck and/or during operation of the mask 20.

Formation of the mask 20, briefly, may include providing the substrate 260, forming the conductive layer 250 on the underside of the substrate 260, forming the multilayer reflector 270 on the topside of the substrate 260, forming the capping layer 200 on the multilayer reflector 270, forming the optional buffer layer 210 on the capping layer 200 and forming the absorber structure 220 on the buffer layer 210 or the capping layer 200. Each of the structures formed on the substrate 260 (e.g., the conductive layer 250, the multilayer reflector 270, the capping layer 200, the optional buffer layer 210 and the absorber structure 220) may be formed by one or more suitable formation operations, which may include an physical vapor deposition (PVD), chemical vapor deposition (CVD), atomic layer deposition (ALD), or the like. Formation of the conductive layer 250 may include any of the methods just mentioned or other methods, such as electroplating, electroless plating, or the like.

Formation of the absorber structure 220 corresponds to act 1010 of FIG. 10. In some embodiments, the absorber structure 220 is or includes a PtRu layer, which may be formed by sputtering, thermal evaporation, metal-organic chemical vapor deposition (MOCVD), atomic layer deposition, electroplating, electrophoretic deposition, chemical solution deposition, nanoparticle deposition, combinations thereof or the like. As described previously, the absorber structure 220 may be or include a high extinction coefficient material which can reduce thickness of the absorber 220. The absorber structure 220 may be formed to a thickness in a range of about 20 nm to about 50 nm.

Following formation of the unpatterned mask 20, the hard mask structure 230 is formed on the unpatterned mask 20, corresponding to acts 1020, 1030, 1040, 1050 of FIG. 10. FIG. 2 depicts four individual hard mask layers 232, 234, 236, 238 included in the hard mask structure 230 on the unpatterned mask 20. Fewer or additional hard mask layers than those shown in FIG. 2 may be included in the hard mask structure 230 in accordance with various embodiments. For example, the hard mask structure 230 may include only third and fourth hard mask layers 236, 238 while first and second hard mask layers 232, 234 are omitted. In another example, the hard mask structure 230 may include the second, third and fourth hard mask layers 234, 236, 238 while the first hard mask layer 232 is omitted. Generally, the bottommost hard mask layer (e.g., the first hard mask layer 232) of the hard mask structure 230 is in direct contact with the upper surface of the uppermost absorber layer (e.g., the second absorber layer 224) of the absorber structure 220. In some embodiments, one or more additional material layers that are not separately depicted in FIG. 2 may intervene between the absorber structure 220 and the hard mask structure 230. Overall thickness of the hard mask structure 230 may be in a range of about 4 nm to about 80 nm in the vertical (e.g., Z-axis) direction.

The first hard mask layer 232 may be formed on the absorber 220, corresponding to act 1020 of FIG. 10. The first hard mask layer 232 may be or include one or more of CrN, Cr2N or the like and may have thickness in the vertical direction that is in a range of about 2 nm to about 20 nm. The first hard mask layer 232 may be formed by reactive sputtering, cathodic arc deposition, thermal CVD, plasma-enhanced CVD (PECVD), ALD, pulsed laser deposition (PLD) or another suitable process.

The second hard mask layer 234 may be formed on the first hard mask layer 232, corresponding to act 1030 of FIG. 10. The second hard mask layer 234 may be or include one or more of TaBN, TaN, MoSi, MoSiN, SiN, SiC, SiCN, combinations thereof or the like and may have thickness in the vertical direction that is in a range of about 2 nm to about 20 nm. In some embodiments, the second hard mask layer 234 is formed by sputtering, e-beam evaporation, thermal CVD, PECVD, MOCVD, ALD, electrochemical deposition, or another suitable process.

The third hard mask layer 236 may be formed on the second hard mask layer 234, corresponding to act 1040 of FIG. 10. The third hard mask layer 236 may be or include one or more of TaBO, Ta₂O₅, TaO₂, TaO, Ta₂O, MoSiO, SiON, SiO₂, SiCON, combinations thereof or the like and may have thickness in the vertical direction that is in a range of about 2 nm to about 20 nm. In some embodiments, the third hard mask layer 236 is formed by sputtering, e-beam evaporation, thermal CVD, PECVD, MOCVD, ALD, electrochemical deposition, or another suitable process.

The fourth hard mask layer 238 may be formed on the third hard mask layer 236, corresponding to act 1050 of FIG. 10. The fourth hard mask layer 238 may be or include one or more of CrON, CrCON, GaN, SiO, SiCO, Y₂O₃, SiCN, SiCON, combinations thereof or the like and may have thickness in the vertical direction that is in a range of about 2 nm to about 20 nm. In some embodiments, the fourth hard mask layer 238 is formed by sputtering, e-beam evaporation, thermal CVD, PECVD, MOCVD, ALD, electrochemical deposition, or another suitable process.

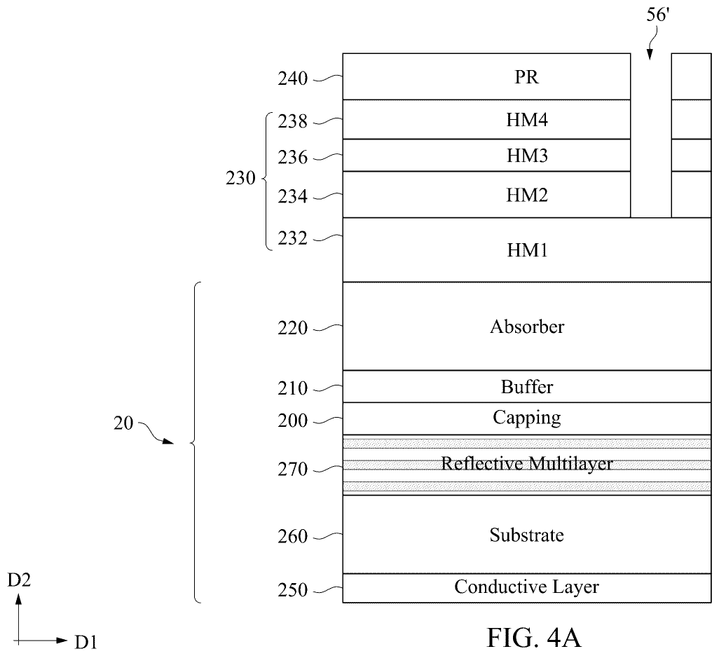

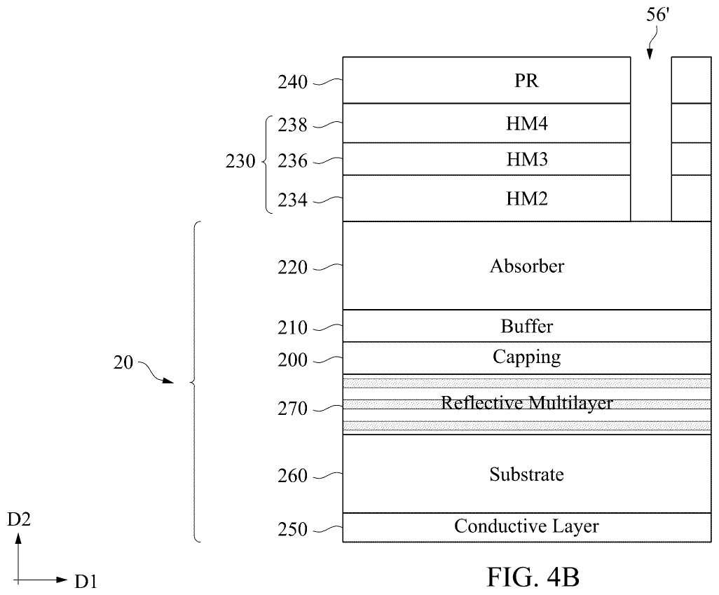

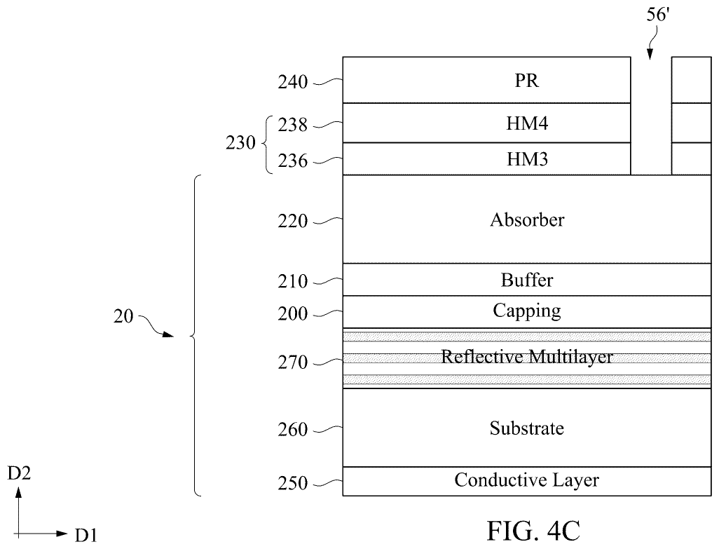

In some embodiments, one or more of the hard mask layers 232, 234, 236, 238 just described may be swapped with another of the hard mask layers 232, 234, 236, 238. For example, positions of the second and third hard mask layers 234, 236 may be swapped such that the third hard mask layer 236 is between the second hard mask layer 234 and the first hard mask layer 232. In another example, the first and fourth hard mask layers 232, 238 may be swapped such that the fourth hard mask layer is directly adjacent or in direct contact with the absorber structure 220. In some embodiments, one or more of the hard mask layers 232, 234, 236, 238 is omitted. For example, the first hard mask layer 232, second hard mask layer 234 or both are omitted in some embodiments, as described with reference to FIGS. 4B and 4C.

Following formation of the hard mask structure 230, a resist layer 240 is formed on the hard mask structure 230. The resist layer 240 may be or include one or more of a photoresist layer, a bottom antireflective coating (BARC) layer, combinations thereof or the like. Selection of the photoresist material and its composition can be beneficial for achieving high resolution and pattern fidelity at nanoscale. Two types of photoresist include positive and negative photoresists, each with compositions selected for specific applications and fabrication requirements. Positive photoresists become more soluble in developer solutions after exposure to light. This property allows the exposed regions to be removed, leaving a pattern where the light has modified the photoresist's solubility. The composition of positive photoresists can include a photoactive compound (PAC), which can be a component that undergoes chemical changes when exposed to light, usually generating a soluble product in the exposed areas. The positive photoresists may include a resin, which can form a bulk of the photoresist and provide mechanical properties thereof. The photoresist may include a solvent, which can be used to adjust viscosity of the photoresist for application purposes. Solvents can be selected for ability to dissolve the resin and PAC and may be evaporated during a prebake process. Negative photoresists become less soluble in the developer solution after exposure to light, such that the exposed areas remain after the development process, creating a negative of the exposure pattern. The composition of negative photoresists often includes a PAC that, unlike in positive resists, cross-links polymer chains in the exposed areas, making them insoluble in the developer. The negative photoresist may include a polymer that provides a structural framework of the photoresist, such as epoxy-based polymers or other polymers that can cross-link upon exposure to light. As with positive photoresists, the negative photoresists may include solvents that adjust the photoresist's viscosity for the coating process and can be selected for ability to dissolve the polymer and PAC. As the semiconductor industry moves towards nanoscale dimensions, photoresists are being developed to provide benefits for extreme ultraviolet (EUV) lithography, electron beam lithography, and immersion lithography. Such “advanced” photoresists can provide higher resolution, lower line edge roughness (LER), and improved sensitivity, and can include chemically amplified resists (CARs) and/or inorganic resists. CARs may be a subclass of both positive and negative resists that use a chemical amplification mechanism to increase sensitivity of the photoresist. This can be achieved through a catalytic reaction initiated by exposure, which allows for the generation of finer patterns. In some embodiments, an inorganic resist may be included in the resist layer 240. The inorganic resist may include a hafnium-based compound for EUV lithography, which can be beneficial for higher resolution patterning due to smaller molecular size and higher etch resistance.

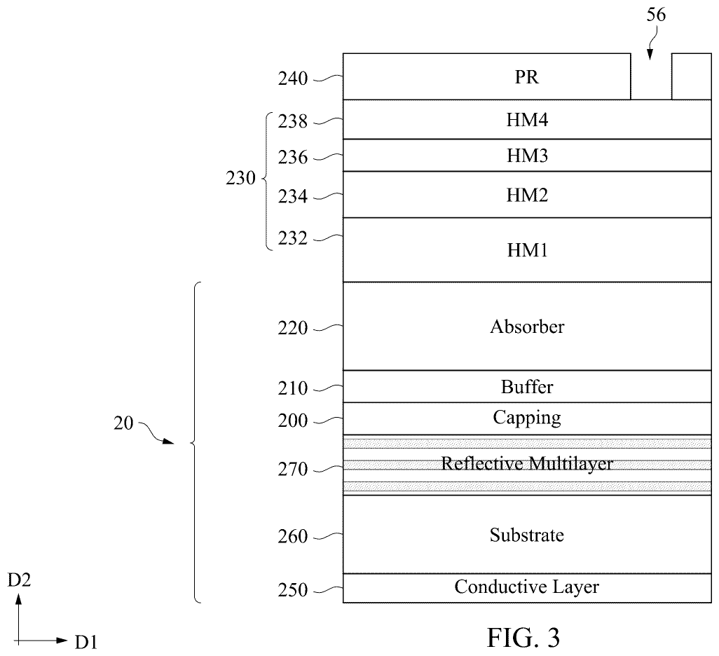

In FIG. 3, a pattern including at least one opening 56 is formed in the resist layer 240. The opening 56 may be formed via electron beam (or “e-beam”) writing, may include one or more baking operations and a development operation. During e-beam writing, a focused beam of electrons can be scanned across a surface of the resist layer 240. The resist layer 240 may be selected to be sensitive to electron beam exposure. Interaction of the electron beam with the resist layer 240 changes solubility thereof in a subsequent development phase. For an EUV photomask, the pattern written by the e-beam corresponds to the mask design, which may include intricate features that will be transferred onto a semiconductor wafer during EUV lithography. E-beam lithography can achieve high resolution and precision, which are beneficial for fabrication of EUV photomasks, which benefit from patterning features at the nanometer scale. The resolution may be determined by factors such as beam size, resist sensitivity and a proximity effect (e.g., a phenomenon where scattered electrons expose nearby areas, potentially leading to unintended exposure).

Prior to e-beam exposure, the resist layer 240 may undergo a pre-exposure bake to remove any solvent and improve adhesion of the resist layer 240 to the substrate (e.g., the absorber 220). This step can be beneficial for increasing resist thickness uniformity and reducing defects. After e-beam exposure, a post-exposure bake may be performed, which can promote chemical reactions initiated by the electron beam exposure within the resist layer 240. For chemically amplified resists (CARs), the baking step can activate an acid catalyst generated during exposure, enabling the acid catalyst to break down or cross-link the polymer of the resist layer 240, depending on whether the resist layer 240 is a positive or negative resist.

Following the post-exposure bake, the development phase can remove either the exposed or unexposed areas of the resist layer 240, depending on whether the resist layer 240 is positive or negative tone. In a positive tone resist, the exposed areas become more soluble and are removed, leaving behind the patterned resist in the unexposed areas of the resist layer 240. In a negative tone resist, the exposed areas become insoluble, and the unexposed areas of the resist layer 240 are washed away. After development, the patterned resist of the resist layer 240 reveals the intricate patterns that will be used in a subsequent etching process to transfer the patterns onto the absorber 220.

The opening 56 at the intermediate stage of fabrication depicted in FIG. 3 may expose the hard mask structure 230. For example, when the fourth hard mask layer 238 is present, the opening 56 may expose an upper surface of the fourth hard mask layer 238. In some embodiments, the opening 56 formed only in the resist layer 240 following initial patterning of the resist layer 240 may expose an upper surface of the fourth hard mask layer 238, the third hard mask layer 236, the second hard mask layer 234 or the first hard mask layer 232.

In FIGS. 4A-7C, the hard mask structure 230 is patterned in accordance with various embodiments, corresponding to act 1060 of FIG. 10.

In FIGS. 4A-4C, in accordance with various embodiments, the opening 56 is extended partially through the hard mask structure 230 by removing portions of one or more of the hard mask layers 232, 234, 236, 238 exposed by the opening 56 in the resist layer 240. FIG. 4A depicts the hard mask structure 230 including four hard mask layers 232, 234, 236, 238. FIG. 4B depicts the hard mask structure 230 including three hard mask layers 234, 236, 238 with the hard mask layer 232 being omitted. FIG. 4C depicts the hard mask structure 230 including two hard mask layers 236, 238 with the hard mask layers 232, 234 being omitted. The hard mask structure 230 can be used to select a minimum feature dimension (“critical dimension” or “CD”) of the mask 20. Minimum feature dimension can refer to a width or length in a horizontal plane of the mask 20 that is perpendicular to the second direction D2 and does not exceed any other width or length in the mask 20. Generally, the hard mask structure 230 includes at least two hard mask layers, such as the hard mask layers 236, 238 and optionally the hard mask layers 232, 234, which is beneficial to improve pattern profile when patterning the one or more absorber layers of the absorber 220. The ruthenium-based material of the absorber 220 may be relatively more difficult to pattern, which results in the increased number of hard mask layers (e.g., two to four layers) being beneficial to generate the selected pattern profile when etching the absorber layer(s) 222, 224. For example, the ruthenium-based material may have relatively high etch resistance to many etching chemicals and/or plasmas, which may increase difficulty selectively removing the ruthenium-based material without substantially affecting adjacent materials, such as those of the hard mask layers 232, 234, 236, 238.

In FIG. 4A, the hard mask structure 230 includes all of the four hard mask layers 232, 234, 236, 238 and an extended opening 56′ is formed by extending the opening 56 through the second, third and fourth hard mask layers 234, 236, 238 resulting in the first hard mask layer 232 being exposed by the extended opening 56′. Extending the opening 56 may include removing portions of the hard mask layers 234, 236, 238 exposed by the opening 56 in the resist layer 240. The removing may include one or more suitable etch operations that remove materials of the hard mask layers 234, 236, 238.

A first etch operation may be performed that removes material of the fourth hard mask layer 238 using the resist layer 240 as a mask. As described previously with reference to FIG. 2, the fourth hard mask layer 238 may be or include CrON, CrCON, GaN, SiO, SiCO, Y₂O₃, SiCN, SiCON or the like, and may have thickness in a range of about 2 nm to about 20 nm. The first etch operation may be an anisotropic etch, such as a dry etch (e.g., reactive ion etch or “RIE” or inductively coupled plasma etch or “ICP”), which may be a fluorine-based dry etch or chlorine-based dry etch. The first etch operation may be a high-density plasma (HDP) etch, an atomic layer etch (ALE) or the like. In some embodiments, the fourth hard mask layer 238 is a layer of CrON and the first etch operation is performed using Cl₂ and O₂ gases. The first etch operation may have directionality that is in the second direction D2, which may be the vertical direction normal to a major surface of the fourth hard mask layer 238. The first etch operation may etch fully through the fourth hard mask layer 238 and may stop on the third hard mask layer 236. In some embodiments, the first etch operation continues slightly into the third hard mask layer 236. The upper surface of the third hard mask layer 236 may be exposed following completion of the first etch operation.

A second etch operation may be performed that removes material of the third hard mask layer 236 using the resist layer 240 and the fourth hard mask layer 238 as a mask. As described previously with reference to FIG. 2, the third hard mask layer 236 may be or include TaBO, Ta₂O₅, TaO₂, TaO, Ta₂O, MoSiO, SiON, SiO₂, SiCON or the like, and may have thickness in a range of about 2 nm to about 20 nm. In FIGS. 4A and 4B, the third hard mask layer 236 includes a material having different etch selectivity than the fourth hard mask layer 238 and the second hard mask layer 234, such that the second etch operation may stop on the second hard mask layer 234. In FIG. 4C, the third mask layer 236 includes material having different etch selectivity than the fourth hard mask layer 238 and the absorber 220, such that the second etch operation may stop on the absorber 220. The second etch operation may be an anisotropic etch, such as a dry etch (e.g., reactive ion etch or “RIE” or inductively coupled plasma etch or “ICP”), which may be a fluorine-based dry etch or chlorine-based dry etch. The second etch operation may be a high-density plasma (HDP) etch, an atomic layer etch (ALE) or the like. Generally, the second etch operation will have different parameters (e.g., reactant types and/or ratio, RF and/or bias power level, pressure, gas flow rate, temperature, substrate bias voltage, plasma composition and the like) than those of the first etch operation such that the second etch operation removes material of the third hard mask layer 236 without substantially attacking the fourth hard mask layer 238 or underlying layers, such as the first or second hard mask layer 232, 234 or the absorber 220. For example, the third hard mask layer 236 may be a layer of TaBO and the second etch operation may use Cl₂ and CF₄ gases. The second etch operation may have directionality that is in the second direction D2, which may be the vertical direction normal to a major surface of the third hard mask layer 236. In the embodiments depicted in FIGS. 4A and 4B, the second etch operation may etch fully through the third hard mask layer 236 and may stop on the second hard mask layer 234. In FIG. 4C, the second etch operation may etch fully through the third hard mask layer 236 and may stop on the absorber 220 or may continue slightly into the absorber 220. The upper surface of the second hard mask layer 234 or the absorber 220 may be exposed following completion of the second etch operation.

In FIGS. 4A and 4B, a third etch operation may be performed that removes material of the second hard mask layer 234 using the resist layer 240 and the third and fourth hard mask layers 236, 238 as a mask. As described previously with reference to FIG. 2, the second hard mask layer 234 may be or include TaBN, TaN, MoSi, MoSiN, SiN, SiC, SiCN or the like, and may have thickness in a range of about 2 nm to about 20 nm. In FIG. 4A, the second hard mask layer 234 includes a material having different etch selectivity than the first, third and fourth hard mask layers 232, 236, 238, such that the third etch operation may stop on the first hard mask layer 232 without substantially attacking the first, third and fourth hard mask layers 232, 236, 238. In FIG. 4B, the second hard mask layer 234 includes a material having different etch selectivity than the absorber 220 and the third and fourth hard mask layers 236, 238, such that the third etch operation may stop on the absorber 220 without substantially attacking the absorber 220 and the third and fourth hard mask layers 232, 236, 238. The third etch operation may be an anisotropic etch, such as a dry etch (e.g., reactive ion etch or “RIE” or inductively coupled plasma etch or “ICP”), which may be a fluorine-based dry etch or chlorine-based dry etch. The third etch operation may be a high-density plasma (HDP) etch, an atomic layer etch (ALE) or the like. Generally, the third etch operation will have different parameters (e.g., reactant types and/or ratio, RF and/or bias power level, pressure, gas flow rate, temperature, substrate bias voltage, plasma composition and the like) than the first and/or second etch operations such that the third etch operation removes material of the second hard mask layer 234 without substantially attacking the third and fourth hard mask layers 236, 238 or underlying layers, such as the first hard mask layer 232 (FIG. 4A) or the absorber 220 (FIG. 4B). For example, the second hard mask layer 234 may be a layer of TaBN and the third etch process may use Cl₂ gas. The third etch operation may have directionality that is in the second direction D2, which may be the vertical direction normal to a major surface of the second hard mask layer 234. In the embodiments depicted in FIG. 4A, the third etch operation may etch fully through the second hard mask layer 236 and may stop on the first hard mask layer 232. In FIG. 4B, the third etch operation may stop on the absorber 220 or may continue slightly into the absorber 220. The upper surface of the first hard mask layer 232 or the absorber 220 may be exposed following completion of the third etch operation.

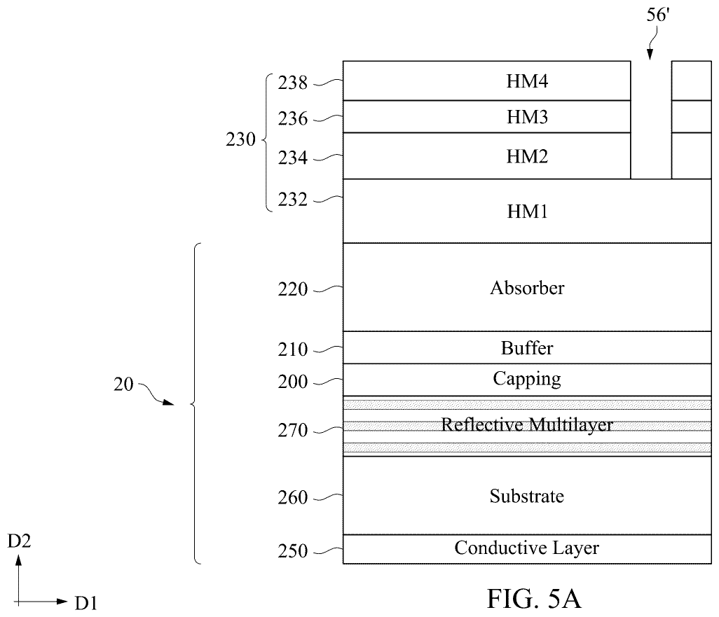

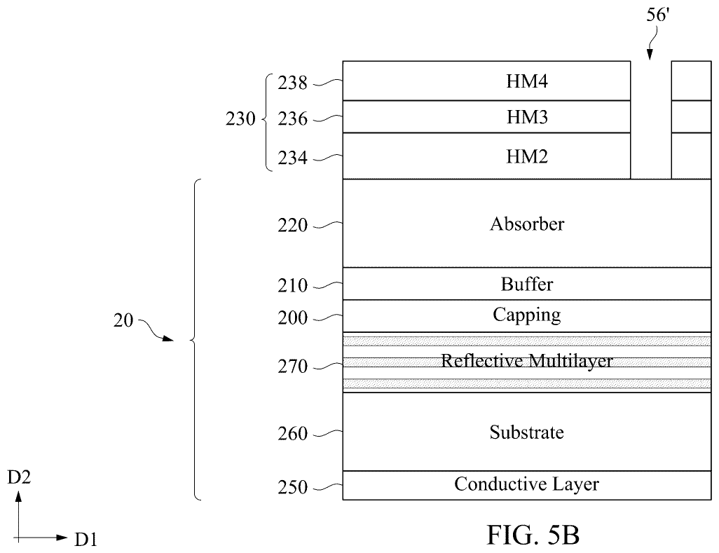

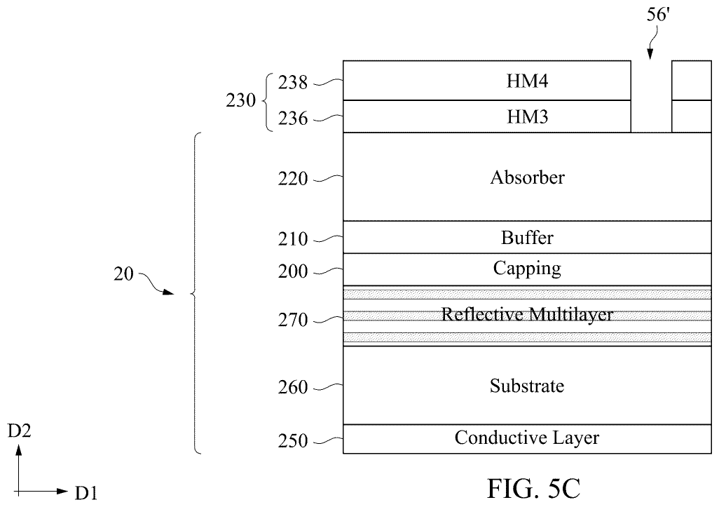

In FIGS. 5A, 5B and 5C, the resist layer 240 is removed, for example, by stripping. FIG. 5A depicts embodiments in which the hard mask structure 230 includes the hard mask layers 232, 234, 236, 238 and the resist layer 240 is removed. FIG. 5B depicts embodiments in which the hard mask structure 230 includes the hard mask layers 234, 236, 238 and the resist layer 240 is removed. FIG. 5C depicts embodiments in which the hard mask structure 230 includes the hard mask layers 236, 238 and the resist layer 240 is removed.

As described with reference to FIGS. 4A-4C, the absorber 220 is exposed by the extended opening 56′ in FIGS. 4B and 4C in which the first hard mask layer 232 and optionally the second hard mask layer 234 is omitted.

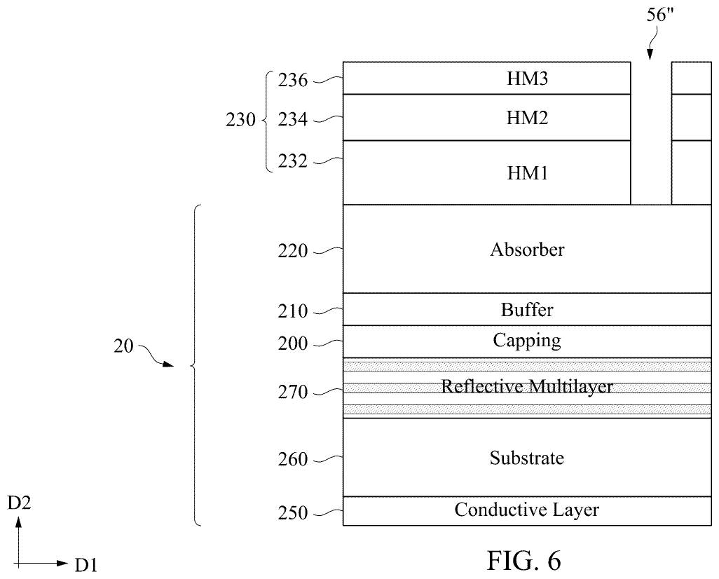

In FIG. 6, following removal of the resist layer 240 in FIG. 5A in which the first and second hard mask layers 232, 234 are present, exposed portions of the first hard mask layer 232 are removed to form an opening 56″ that exposes the absorber 220. As described with reference to FIG. 2, the absorber 220 may include a single layer 222 or 224 or a multilayer including at least two layers 222, 224. The opening 56″ may expose the single layer 222 or 224 or an uppermost layer of the multilayer 220, such as the absorber layer 224.

The opening 56″ may be formed by performing one or more suitable etch operations to remove portions of the first hard mask layer 232 exposed by the extended opening 56″. As described previously with reference to FIG. 2, the first hard mask layer 232 may be or include CrN, Cr₂N or the like, and may have thickness in a range of about 2 nm to about 20 nm. The fifth etch operation may be an anisotropic etch, such as a dry etch (e.g., reactive ion etch or “RIE” or inductively coupled plasma etch or “ICP”), which may be a fluorine-based dry etch or chlorine-based dry etch. The fifth etch operation may be a high-density plasma (HDP) etch, an atomic layer etch (ALE) or the like. For example, a fifth etch operation may be performed to remove the exposed portions of the first hard mask layer 232 using the second, third and fourth hard mask layers 234, 236, 238 as a mask. In some embodiments, the first hard mask layer 232 is or includes CrN and the fifth etch operation uses Cl₂ and O₂ gases as reactant gases in an anisotropic etch. The fifth etch operation may have directionality that is in the second direction D2, which may be the vertical direction normal to a major surface of the first hard mask layer 232. The fifth etch operation may etch fully through the first hard mask layer 232 and may stop on the absorber 220. In some embodiments, the fifth etch operation continues slightly into the absorber 220. The upper surface of the absorber 220 may be exposed following completion of the fifth etch operation. As discussed above, the first hard mask layer 232 may be patterned using one or more other hard masks disposed above the first hard mask layer. This feature may provide more fine-tuning of the minimum feature dimension (“critical dimension” or “CD”) in preparation for patterning of the absorber 220.

The fifth etch operation may be omitted in the embodiments described with reference to FIGS. 4B, 4C, 5B and 5C, in which the extended opening 56′ directly exposes the absorber 220.

In some embodiments, as depicted in FIG. 6, the fifth etch operation removes the fourth hard mask layer 238.

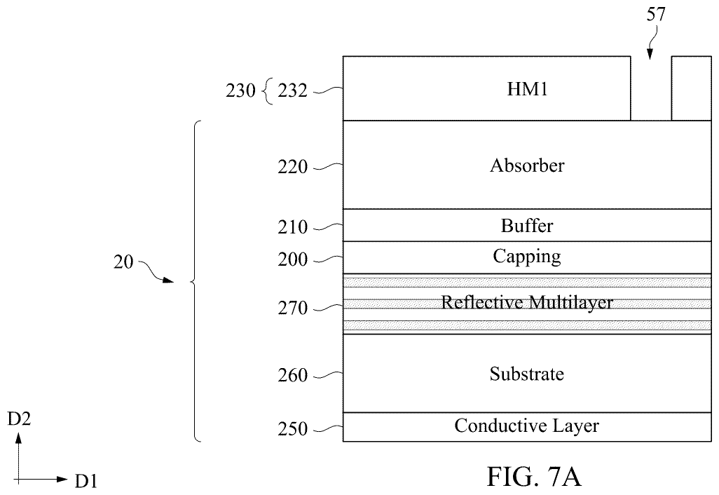

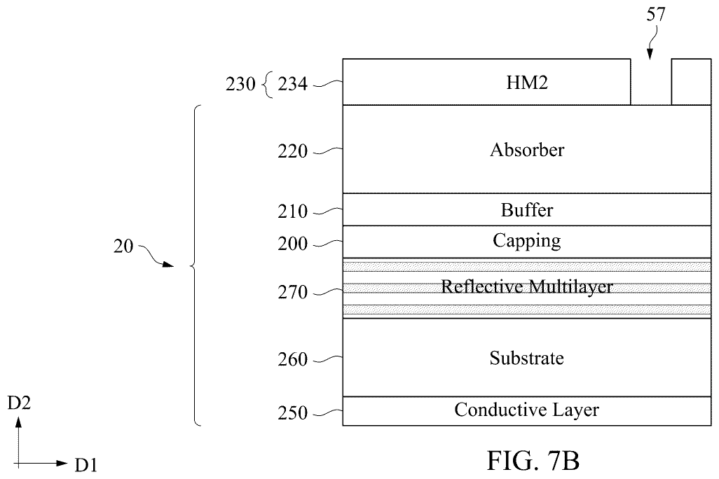

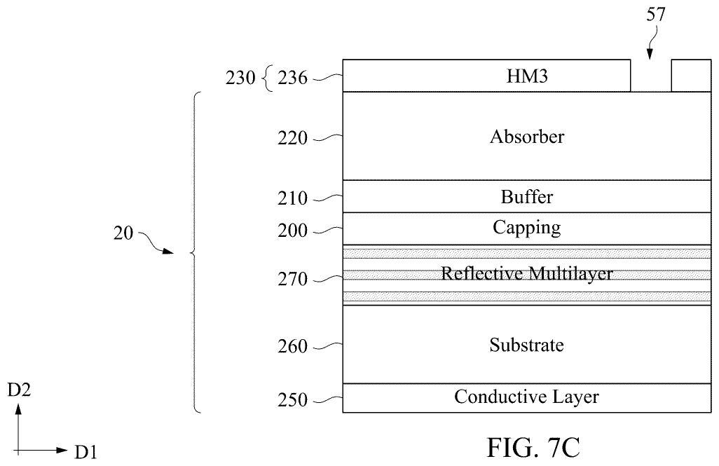

FIGS. 7A, 7B and 7C depict removal of any remaining hard mask layers other than a bottommost hard mask layer of the hard mask structure 230 that is in nearest proximity to (e.g., in direct contact with) the absorber 220.

In FIG. 7A, the second and third hard mask layers 234, 236 are removed leaving the first hard mask layer 232 in place on the absorber 220. Upper portions of the opening 56″ are removed, leaving an opening 57 in the first hard mask layer 232 that exposes a portion of the absorber 220. The second and third hard mask layers 234, 236 may be removed by one or more suitable removal operations, such as a stripping operation(s), followed by a cleaning operation. For example, a wet chemical stripping, dry etch or other suitable process may be performed that removes the second and third hard mask layers 234, 236 without substantially altering or damaging the underlying structure, such as the first hard mask layer 232 and the absorber 220.

In FIG. 7B, the third and fourth hard mask layers 236, 238 are removed leaving the second hard mask layer 234 in place on the absorber 220. Upper portions of the opening 56″ are removed, leaving an opening 57 in the second hard mask layer 234 that exposes a portion of the absorber 220. The third and fourth hard mask layers 236, 238 may be removed by one or more suitable removal operations, such as a stripping operation(s), followed by a cleaning operation. For example, a wet chemical stripping, dry etch or other suitable process may be performed that removes the third and fourth hard mask layers 236, 238 without substantially altering or damaging the underlying structure, such as the second hard mask layer 234 and the absorber 220.

In FIG. 7C, the fourth hard mask layer 238 is removed leaving the third hard mask layer 236 in place on the absorber 220. Upper portions of the opening 56″ are removed, leaving an opening 57 in the third hard mask layer 236 that exposes a portion of the absorber 220. The fourth hard mask layer 238 may be removed by a suitable removal operation, such as a stripping operation, followed by a cleaning operation. For example, a wet chemical stripping, dry etch or other suitable process may be performed that removes the fourth hard mask layer 238 without substantially altering or damaging the underlying structure, such as the third hard mask layer 236 and the absorber 220.

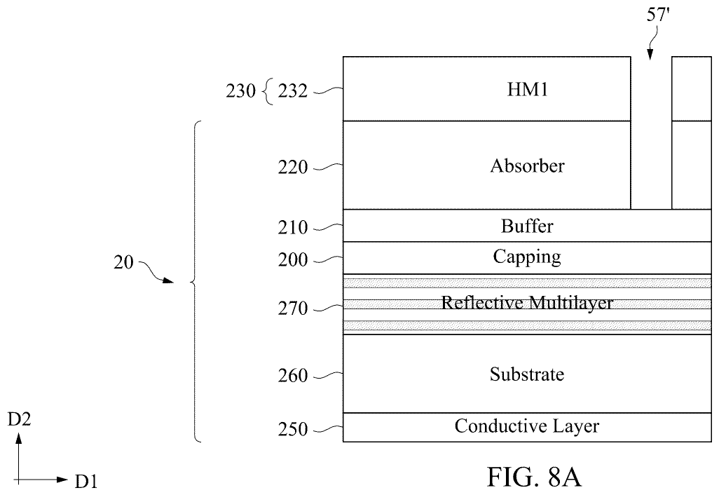

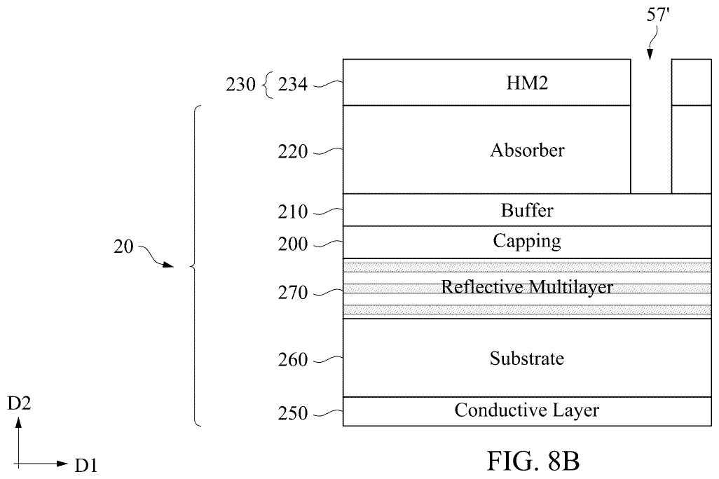

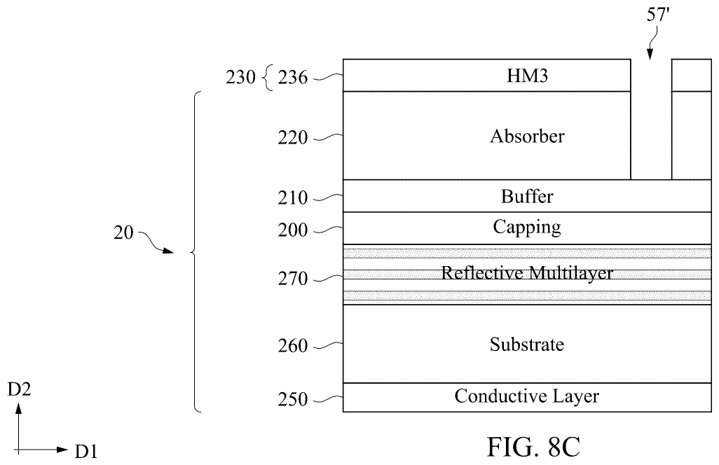

In FIGS. 8A, 8B, 8C, following removal of the upper hard mask layer(s) as described with reference to FIGS. 7A-7C, the absorber 220 is patterned, corresponding to act 1070 of FIG. 10. The absorber 220 may be patterned by removing exposed portions of the absorber 220 using the hard mask structure 230 (e.g., the first, second or third hard mask layer 232, 234, 236) as a mask. As described with reference to FIG. 2, the absorber 220 may include a single layer 222 or 224 or may be a multilayer including at least two layers 222, 224. For example, the absorber 220 may include PtRuO, IrRuO, OsRuO, HfRuO, RhRuO, PtRuON, IrRuON, OsRuON, HfRuON, RhRuON, RuTa, RuTaO, PtRu, IrRu, OsRu, HfRu, RhRu, PtRuN, IrRuN, OsRuN, HfRuN, RhRuN or the like. Openings 57′ that extend through the layer(s) of the absorber 220 are formed to expose the buffer layer 210.

In FIG. 8A, the exposed portions of the absorber 220 may be etched via a sixth and/or seventh etch operation that forms extended openings 57′ that expose the buffer layer 210 using the first hard mask layer 232 as a mask. In embodiments in which the absorber 220 is a single layer, the single layer may be etched using the sixth etch operation. In embodiments in which the absorber 220 includes a bilayer or multilayer, the bilayer or multilayer may be etched using the sixth and seventh etch operations and optionally additional etch operations. The sixth and/or seventh etch operations may each be an anisotropic etch, such as a dry etch (e.g., reactive ion etch or “RIE” or inductively coupled plasma etch or “ICP”), which may be a fluorine-based dry etch or chlorine-based dry etch. The sixth and/or seventh etch operation may each be a high-density plasma (HDP) etch, an atomic layer etch (ALE) or the like. In some embodiments, the absorber 220 includes a single PtRu layer and the sixth etch operation uses CF₄ and O₂ as reactant gases.

In FIG. 8B, the exposed portions of the absorber 220 may be etched via a sixth and/or seventh operation that forms extended openings 57′ that expose the buffer layer 210 using the second hard mask layer 234 as a mask. The etching may be similar to that described with reference to FIG. 8A. The sixth and/or seventh operation may be an anisotropic etch, such as a dry etch (e.g., reactive ion etch or “RIE” or inductively coupled plasma etch or “ICP”), which may be a fluorine-based dry etch or chlorine-based dry etch. The sixth and/or seventh operation may be a high-density plasma (HDP) etch, an atomic layer etch (ALE) or the like. In some embodiments, the absorber 220 includes a single PtRu layer and the sixth etch operation uses CF₄ and O₂ as reactant gases.

In FIG. 8C, the exposed portions of the absorber 220 may be etched via a sixth and/or seventh operation that forms extended openings 57′ that expose the buffer layer 210 using the third hard mask layer 236 as a mask. The etching may be similar to that described with reference to FIG. 8A. The sixth and/or seventh operation may be an anisotropic etch, such as a dry etch (e.g., reactive ion etch or “RIE” or inductively coupled plasma etch or “ICP”), which may be a fluorine-based dry etch or chlorine-based dry etch. The sixth and/or seventh operation may be a high-density plasma (HDP) etch, an atomic layer etch (ALE) or the like. In some embodiments, the absorber 220 includes a single PtRu layer and the sixth etch operation uses CF₄ and O₂ as reactant gases.

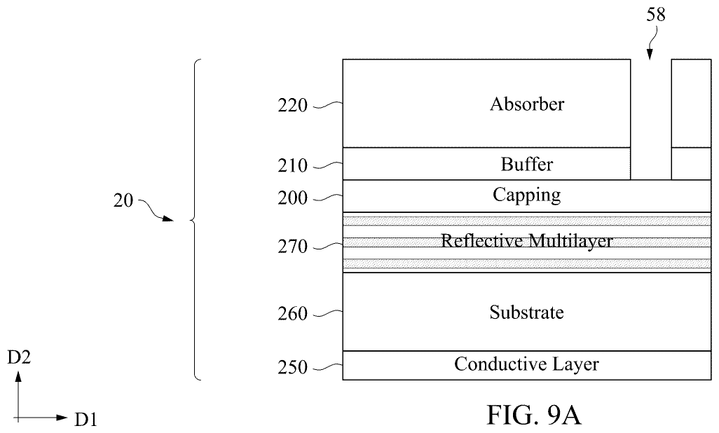

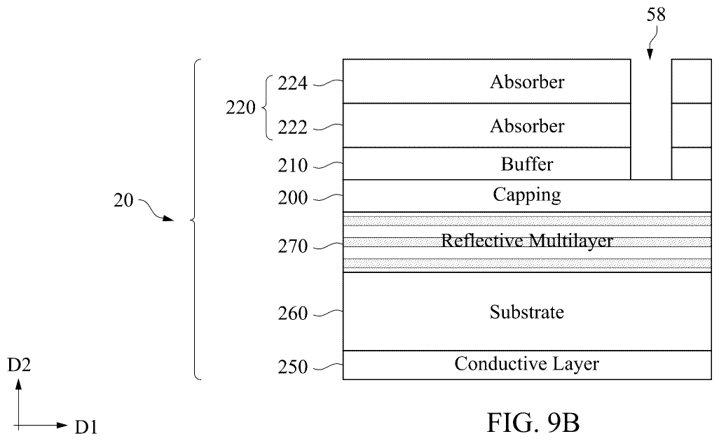

FIGS. 9A and 9B depict formation of an opening 58 that exposes the capping layer 200 overlying the reflective multilayer 270. The opening 58 may be one of a plurality of openings 58 that are arranged in the absorber 220 according to a pattern. The pattern including the openings 58 allows incident light to be absorbed by the absorber 220 outside the openings 58 and allows the incident light to be reflected by the reflective multilayer 270 via the openings 58. In FIG. 9A, the absorber 220 includes a single layer, which may be the absorber layer 222 or the absorber layer 224 described with reference to FIG. 2. In FIG. 9B, the absorber 220 includes a multilayer, such as a bilayer including the absorber layer 222 and the absorber layer 224.

In FIGS. 9A and 9B, following formation of the extended opening 57′ that exposes the buffer layer 210 in FIGS. 8A-8C, an opening 58 that exposes the capping layer 200 is formed by removing a portion of the buffer layer 210 exposed by the extended opening 57′. The buffer layer 210 may be or include a layer of CrN or Cr₂N. The opening 58 may be formed by a removal operation that is selective to material of the buffer layer 210. In some embodiments, the first hard mask layer 232 is in place and has a material that is similar to or the same as that of the buffer layer 210. As a non-limiting example, the hard mask layer 232 and the buffer layer 210 may each be formed by the same material as each other, the material including TaBO, TaBN, TaN, Ta2O5, TaO2, TaO, Ta2O, MoSi, MoSiN, MoSiO, SiN, SiON, SiO2, SiCON, SiC, SiCN, CrN, Cr2N, or GaN. In such embodiments, the removal operation may be a stripping operation that removes the first hard mask layer 232 and the exposed portion of the buffer layer 210 simultaneously. The removal operation may include wet chemical etching, dry etching (e.g., RIE, ICP) or another suitable process. In embodiments in which the removal operation is performed with the second or third hard mask layer 234, 236 in place, the second or third hard mask layer 234, 236 may be removed separately from the removal of the exposed portion(s) of the buffer layer 210. For example, the second or third hard mask layer 234, 236 may be removed following the removal of the exposed portion(s) of the buffer layer 210.

The mask 20 depicted in FIGS. 9A and 9B includes the absorber 220 having high-K materials, which can reduce the thickness of the absorber film 220, which in turn reduces M3D effects and exposure energy and improves image quality. The absorber layer 220 including the high-K materials can be a single layer, a bilayer or a multilayer. Ru-based alloys can be included in the absorber layer(s) 220, such as PtRu, IrRu, OsRu, HfRu, RhRu, PtRuN, IrRuN, OsRuN, HfRuN, RhRuN, PtRuO, IrRuO, OsRuO, HfRuO, RhRuO, PtRuON, IrRuON, OsRuON, HfRuON, RhRuON and the like. The hard mask structure 230 and buffer layer 210 provide improved patterning through dry etching.

FIG. 11 is a flowchart of a process 2000 for forming an integrated circuit die using a mask including a high extinction coefficient absorber in accordance with various embodiments. In some embodiments, the process 2000 includes a number of operations (2010, 2020, 2030). In some embodiments, the process 2000 may be used to pattern a wafer layer as an intermediate step in forming the integrated circuit die via the mask having the high-K absorber. The process 2000 is described according to one or more embodiments. The operations of the process 2000 may be rearranged or otherwise modified within the scope of the various aspects. Additional processes may be provided before, during and after the process 2000, and some other processes may be only briefly described herein. In some embodiments, the process 2000 is performed by the system 10 described with reference to FIGS. 1A and 1B utilizing the mask 20 described with reference to FIGS. 2-9B. The embodiments of the process 2000 are described with reference to the structural elements described with reference to FIGS. 1A and 1B and FIGS. 9A and 9B, but the process 2000 may be performed by a system having one or more structural elements that are different from those of the system 10 and a mask having one or more structural elements that are different from those of the mask 20. The process 2000 of FIG. 11 may be combined with the system 10 and the mask 20 described with reference to FIGS. 1A and 1B and 2-9B.

In act 2010, EUV radiation is generated. The EUV radiation may be similar to the light 84 described with reference to FIGS. 1A and 1B.

In act 2020, the EUV radiation is patterned by a mask having a high-K absorber. The mask may be similar to the mask 20 described with reference to FIGS. 2-9B. The high-K absorber can reduce thickness of the absorber, which in turn reduces M3D effects and exposure energy and improves image quality. The absorber including the high-K materials can be a single layer, a bilayer or a multilayer. Ru-based alloys can be included in the high-K absorber, such as PtRu, IrRu, OsRu, HfRu, RhRu, PtRuN, IrRuN, OsRuN, HfRuN, RhRuN, PtRuO, IrRuO, OsRuO, HfRuO, RhRuO, PtRuON, IrRuON, OsRuON, HfRuON, RhRuON and the like.

In act 2030, the patterned EUV radiation reflected from the reflective multilayer having portions exposed by openings in the high-K absorber may be directed toward a layer of a wafer to expose the wafer layer according to the pattern of the mask. For example, the EUV radiation 84 may be reflected by the reflective multilayer 270 of the mask 20 that has the pattern of the openings 58 in the absorber 220. The patterned EUV radiation may be directed to a layer 26 on a wafer 22 via the projection optics box 180 described with reference to FIG. 1A. In some embodiments, the layer 26 is a photosensitive resist layer. While not necessarily identical to the resist layer 240 described with reference to FIG. 2, patterning of the layer 26 may be similar in most respects to that described with reference to FIG. 2. For example, the layer 26 may include positive or negative tone photoresist that may be patterned via exposure to the patterned EUV light so as to increase or decrease solubility of the exposed regions of the layer 26, followed by a development process that removes exposed or unexposed regions of the layer 26 to form openings in the layer 26. An underlying layer positioned under the layer 26 may be patterned (e.g., etched via a suitable etching operation) using the layer 26 as a mask. The etching operation, while not necessarily identical to those described with reference to FIGS. 3A-9B, may be similar in many respects to those described, such as an anisotropic etch, which may be a dry etch.

Embodiments may provide advantages. The high extinction coefficient absorber 220 includes one or more Ru-based alloy materials, which allows for reduced thickness of the absorber 220, which can reduce M3D effects and exposure energy while increasing image quality. The hard mask structure 230 and buffer layer 210 allow for improved patterning through dry etching.

In accordance with at least one embodiment, a method includes: forming a mask layer on a semiconductor wafer; generating extreme ultraviolet (EUV) light by a lithography exposure system; forming patterned EUV light by patterning the EUV light by a mask including an absorber having extinction coefficient at an EUV wavelength that exceeds extinction coefficients of TaBN and TaN at the EUV wavelength; and exposing the mask layer by the patterned EUV light.

In accordance with at least one embodiment, a method includes: forming a reflective multilayer on a substrate, the reflective multilayer being operable to reflect extreme ultraviolet (EUV) light; forming an absorber layer over the reflective multilayer, the absorber layer including ruthenium; forming a hard mask structure over the absorber layer; forming an opening in the hard mask structure; and forming an absorber by removing a portion of the absorber layer exposed by the opening in the hard mask structure.

In accordance with at least one embodiment, an extreme ultraviolet (EUV) mask includes: a substrate; a reflective multilayer over the substrate; and an absorber over the reflective multilayer, the absorber including a ruthenium-based material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a mask layer on a semiconductor wafer;
generating extreme ultraviolet (EUV) light by a lithography exposure system;
forming patterned EUV light by patterning the EUV light by a mask including an absorber having extinction coefficient at an EUV wavelength that exceeds extinction coefficients of TaBN and TaN at the EUV wavelength; and
exposing the mask layer by the patterned EUV light.

2. The method of claim 1, wherein the forming patterned EUV light includes forming the patterned EUV light by the mask including the absorber having a ruthenium-based alloy.

3. The method of claim 1, wherein the forming patterned EUV light includes forming the patterned EUV light by the mask including the absorber having:
a first absorber layer having a first ruthenium-based alloy; and
a second absorber layer on the first absorber layer, the second absorber layer having a second ruthenium-based alloy different than the first ruthenium-based alloy.

4. The method of claim 1, wherein the forming patterned EUV light includes forming the patterned EUV light by the mask including:
a reflective multilayer;
a buffer layer on the reflective multilayer; and
the absorber on the buffer layer.

5. The method of claim 4, wherein the forming patterned EUV light includes forming the patterned EUV light by the mask further including a capping layer between the reflective multilayer and the buffer layer.

6. The method of claim 5, wherein the forming patterned EUV light includes forming the patterned EUV light by reflecting the EUV light via portions of the reflective multilayer exposed by openings that extend through the absorber and the buffer layer.

7. A method, comprising:
forming a reflective multilayer on a substrate, the reflective multilayer being operable to reflect extreme ultraviolet (EUV) light;
forming an absorber layer over the reflective multilayer, the absorber layer including ruthenium;
forming a hard mask structure over the absorber layer;
forming an opening in the hard mask structure; and
forming an absorber by removing a portion of the absorber layer exposed by the opening in the hard mask structure.

8. The method of claim 7, wherein the forming a hard mask structure includes:
forming a first hard mask layer on the absorber layer, the first hard mask layer including a first material; and
forming a second hard mask layer on the first hard mask layer, the second hard mask layer including a second material different than the first material.

9. The method of claim 8, wherein the forming a hard mask structure includes:
forming a third hard mask layer on the second hard mask layer, the third hard mask layer including a third material different than the first and second materials.

10. The method of claim 9, wherein the forming a hard mask structure includes:
forming a fourth hard mask layer on the third hard mask layer, the fourth hard mask layer including a fourth material different than the first, second and third materials.

11. The method of claim 10, wherein the forming an absorber includes:
forming an opening through the second, third and fourth hard mask layers;
forming an extended opening by etching the first hard mask layer through the opening; and
during the forming an extended opening, removing the fourth hard mask layer.

12. The method of claim 10, further comprising, prior to the forming an absorber layer, forming a buffer layer on the reflective multilayer, the buffer layer including the first material.

13. The method of claim 12, further comprising, during removing a portion of the buffer layer exposed by the absorber, removing the first hard mask layer.

14. The method of claim 7, wherein the forming a hard mask structure includes forming at least two hard mask layers, each of the at least two hard mask layers having thickness in a range of about 2 nanometers to about 20 nanometers.

15. An extreme ultraviolet (EUV) mask, comprising:
a substrate;
a reflective multilayer over the substrate; and
an absorber over the reflective multilayer, the absorber including a ruthenium-based material.

16. The EUV mask of claim 15, further comprising:
a capping layer over the reflective multilayer; and
a buffer layer between the capping layer and the absorber.

17. The EUV mask of claim 16, wherein the buffer layer includes TaBN, TaN, MoSi, MoSiN, SiN, SiC or SiCN.

18. The EUV mask of claim 15, wherein the absorber includes a layer of a first material, the first material being PtRuO, IrRuO, OsRuO, HfRuO, RhRuO, PtRuON, IrRuON, OsRuON, HfRuON, RhRuON, RuTa or RuTaO.

19. The EUV mask of claim 15, wherein the absorber includes a layer of a second material, the second material being PtRu, IrRu, OsRu, HfRu, RhRu, PtRuN, IrRuN, OsRuN, HfRuN or RhRuN.

20. The EUV mask of claim 15, wherein the absorber includes at least one absorber layer, the at least one absorber layer having grain size that does not exceed about 5 nanometers.
